(19) United States
(12) Patent Application Publication
(10) Pub. No.: US 2025/0006732 A1
(43) Pub. Date: Jan. 2, 2025

(54) SEMICONDUCTOR DEVICE HAVING DIELECTRIC GATE ISOLATION SECTION

(71) Applicant: Taiwan Semiconductor Manufacturing Company, Ltd., Hsinchu (TW)

(72) Inventor: Chia-Yi Wu, Taichung City (TW)

(21) Appl. No.: 18/345,988

(22) Filed: Jun. 30, 2023

(51) Int. Cl. H01L 27/088; H01L 21/8234

(52) U.S. Cl. CPC H01L 27/0886; H01L 21/823481

(57) ABSTRACT

Semiconductor devices and fabrication methods are provided. In one example, a semiconductor device includes: a substrate, a fin formed on the substrate, a gate structure formed on the fin, a metal contact formed on the fin and adjacent to the gate structure. The fin extends along a first horizontal direction, the gate structure and the metal contact extend along a second horizontal direction, and the second horizontal direction is perpendicular to the first horizontal direction. The gate structure further includes a gate electrode coupled to the fin and a dielectric gate isolation section separated from the gate electrode. The dielectric gate isolation section includes a dielectric material. A portion of the dielectric gate isolation section is aligned with a portion of the metal contact adjacent and proximate to the dielectric gate isolation section in the first horizontal direction.

### FIELD

Embodiments of the present disclosure relate generally to semiconductor devices, and more particularly to fin field effect transistor (FinFET) devices.

### BACKGROUND

The semiconductor integrated circuit (IC) industry has experienced exponential growth. Technological advances in IC materials and design have produced generations of ICs where each generation has smaller and more complex circuits than the previous generation. The smaller feature size is the use of multi-gate devices such as fin field effect transistor (FinFET) devices. FinFETs are so called because a gate is present on and around a “fin” that extends from the substrate. FinFET devices may allow for shrinking the gate width of device while providing a gate on the sides and/or top of the fin including the channel region.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram illustrating a top view of a layout of a semiconductor device, in accordance with some embodiments.

FIG. 1B is a schematic diagram illustrating a cross-sectional view of the semiconductor device of FIG. 1A, in accordance with some embodiments.

FIG. 1C is a schematic diagram illustrating another cross-sectional view of the semiconductor device of FIG. 1A, in accordance with some embodiments.

FIG. 2 is a flowchart diagram illustrating an example method of fabricating a semiconductor device, in accordance with some embodiments.

FIGS. 3A-3M are schematic diagrams illustrating top views or cross-sectional views of a semiconductor device at various fabrication stages in accordance with some embodiments.

FIG. 4 is a schematic diagram illustrating a top view of a layout of a semiconductor device, in accordance with some embodiments.

FIG. 5 is a schematic diagram illustrating a top view of a layout of another semiconductor device, in accordance with some embodiments.

FIG. 6 is a schematic diagram illustrating a top view of a layout of yet another semiconductor device, in accordance with some embodiments.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, source/drain region(s) may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

### Overview

In recent development of semiconductor devices, particularly semiconductor devices having multiple active regions and transistors, gate isolation sections (sometimes also referred to as “gate isolation structures” or “dummy gate sections”) are usually used to separate a gate structure into multiple functional sections and/or isolate gate electrodes of a gate structure in different active regions. For example, a conventional gate isolation section (sometimes also referred to as a “dummy PO”) of a gate structure may be formed using a cut poly (sometimes also referred to as “CPO”) process. Such conventional gate isolation section is typically composed of a conductive material such as polysilicon. As a result, significant parasitic capacitance can be generated between the conventional gate isolation section and another conductive element (e.g., a metal contact) adjacent to the conventional gate isolation section. Parasitic capacitance can cause increased power consumption and/or reduced operation speed of the semiconductor device. Thus, such parasitic capacitance may seriously degrade the performance of the semiconductor device.

The present disclosure provides novel techniques to address the above-mentioned problems. In one or more embodiments, by forming a dielectric gate isolation section (i.e., a section composed of a dielectric material in a gate structure), parasitic capacitance is reduced between the dielectric gate isolation section and a conductive element adjacent to or nearby the dielectric gate isolation section. As a result, a semiconductor device with increased operation speed and/or reduced power consumption compared to the other approaches is obtainable. In addition, the dielectric gate isolation sections may also prevent or reduce the gain-to-drain leakage, which is usually generated by the conventional gate isolation section composed of a conductive material. The dielectric gate isolation sections according to the present disclosure may be formed by using original CPO pattern used in the fabrication process without additional patterning. In at least one embodiment, one or more of the described effects, such as circuit density, performance and power consumption improvements, are achievable without extra cost and/or area penalty.

Example Semiconductor Devices with Dielectric Gate Isolation Section

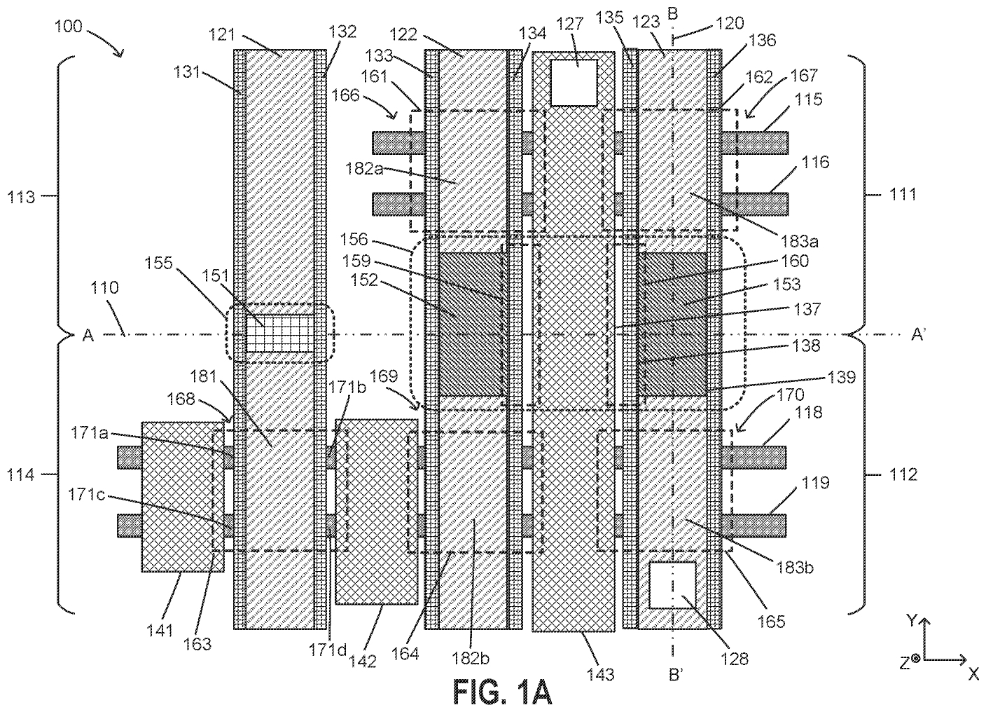

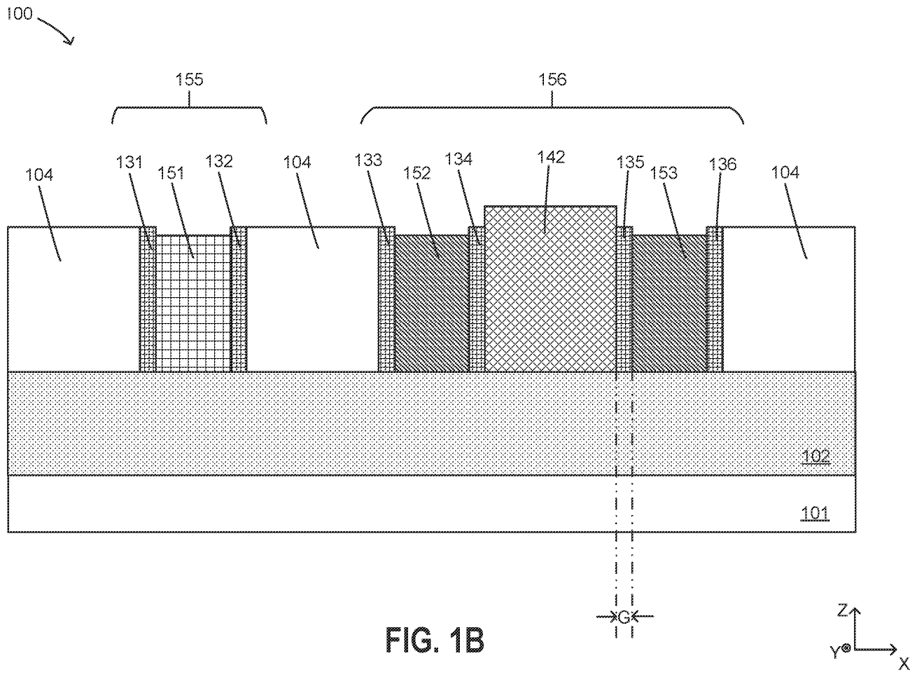

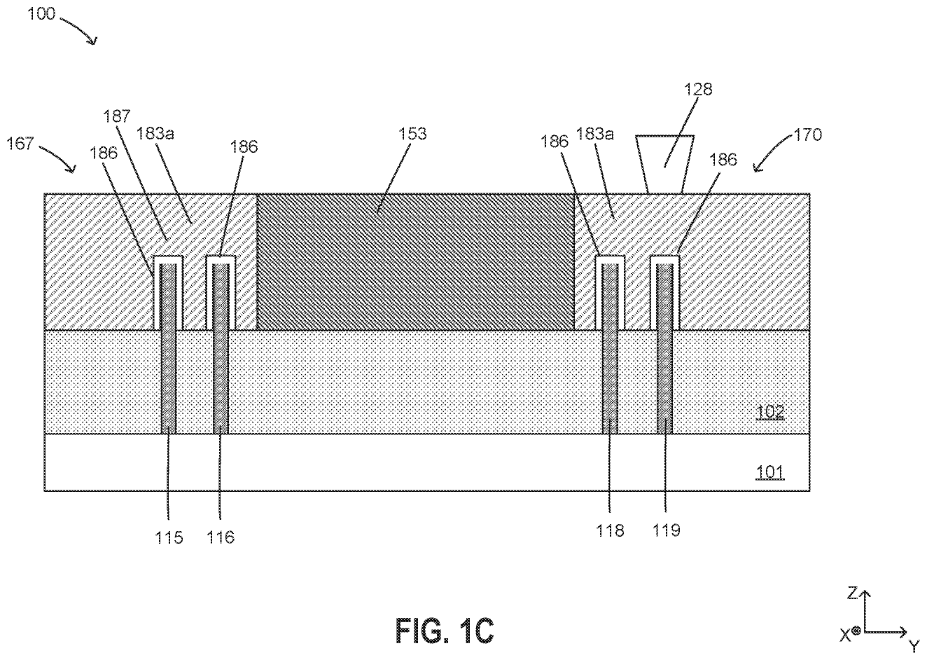

FIG. 1A is a top view of a layout of a semiconductor device 100, in accordance with some embodiments. FIG. 1B is a cross-sectional view of the semiconductor device 100 along an imaginary line 110 from A to A′ in a first direction (i.e., the first horizontal direction, or the latitudinal direction, or X-direction). FIG. 1C is a cross-sectional view of the semiconductor device 100 along an imaginary line 120 from B to B′ in a second direction (i.e., the second horizontal direction, or the longitudinal direction, or Y-direction). In the illustrated example, the layout of semiconductor device 100 includes, among other components or elements, a plurality of active regions including a first active region 111 and a second active region 112, a plurality of gate structures 121, 122, and 123, one or more gate isolation sections 151, 152, 153 respectively formed on the gate structures 121, 122, and 123, a plurality of gate spacers 131, 132, 133, 134, 135, and 136, and a plurality of metal contacts 141, 142, and 143.

The semiconductor device 100 may include a substrate 101 over which various components or elements of the semiconductor device 100 are formed. The elements of the semiconductor device 100 include active elements and/or passive elements. In at least one embodiment, active elements are arranged in a circuit region of the semiconductor device to provide one or more functions and/or operations intended to be performed by the semiconductor device. In at least one embodiment, the semiconductor device further includes a non-circuit region, e.g., a sealing region, that extends around and protects the circuit region. Examples of active elements include, but are not limited to, transistors and diodes. Examples of transistors are described herein with respect to FIG. 1A. Examples of passive elements include, but are not limited to, capacitors, inductors, fuses, and resistors. A plurality of metal layers and via layers are alternatingly formed over the substrate 101 to electrically couple the elements of the semiconductor device 100 with each other and/or with external devices. The substrate 101 includes, in at least one embodiment, a silicon substrate. The substrate 101 includes, in at least one embodiment, silicon germanium (SiGe), Gallium arsenic, p-type doped Si, N-type doped Si, or suitable semiconductor materials. For example, semiconductor materials including group III, group IV, and group V elements are within the scope of various embodiments. In some embodiments, the substrate 101 further includes one or more other features, such as various doped regions, a buried layer, and/or an epitaxy (epi) layer. In some embodiments, the substrate 101 includes a semiconductor on insulator, such as silicon on insulator (SOI). In some embodiments, the substrate 101 includes a doped epi layer, a gradient semiconductor layer, and/or a semiconductor layer overlying another semiconductor layer of a different type such as a silicon layer on a silicon germanium layer.

The active regions 111, 112 extend along the X-direction of the layout of the semiconductor device 100. In some embodiments, the active regions 111, 112 are also referred to as oxide-definition (OD) regions. Example materials of the active area regions 111, 112 include, but are not limited to, semiconductor materials doped with various types of p-dopants and/or n-dopants. In at least one embodiment, the active regions 111, 112 include dopants of the same type. In at least one embodiment, one of the active regions 111, 112 includes dopants of a type different from a type of dopants of another one of the active regions 111, 112. The active regions 111, 112 may be isolated from each other by one or more gate isolation sections as described herein. In some embodiments, the active regions 111, 112 are within corresponding well regions. For example, the active region 111 may be within a well region 113 which is an n-well region in one or more embodiments, and the active region 112 is within a well region 114 which is a p-well region in one or more embodiments. The described conductivity of the well regions 113, 114 is an example. Other arrangements are within the scope of various embodiments.

The n-well region 113 and the p-well region 114 are on opposite sides of the imaginary line 110 which may divide the semiconductor device 100 into separate regions for different types of devices or transistors. Examples of transistors include, but are not limited to, metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), FinFETs, planar MOS transistors with raised source/drains, or the like. In the illustrated example of FIGS. 1A-1C, the n-well region 113 is a region for forming p-channel metal-oxide semiconductor (PMOS) transistors, and the p-well region 114 is a region for forming n-channel metal-oxide semiconductor (NMOS) transistors. Each of the active regions 111, 112 has one or more fins to form FinFETs. For example, the active area region 111 has two fins 115, 116, and the active region 112 has two fins 118, 119. Other numbers of fins in each of the active area regions 111, 112 are within the scope of various embodiments. In the illustrated example, the first active region 111 includes two transistor regions (i.e., FinFET regions) 161 and 162, and the second active region 112 includes three transistor regions 163, 164, and 165. The transistor regions 161, 162, 163, 164, and 165 respectively include FinFET 166, 167, 168, 169, and 170. The described FinFET configuration is an example. Other arrangements are within the scope of various embodiments. For example, in one or more embodiments, the active regions 111, 112 do not include fins and are configured for forming planar MOSFET transistors.

One or more shallow trench isolation (STI) structures 102 are formed on the substrate 101 to define and electrically isolate the fins 115, 116, 118, and 119. Example materials of the STI structure 102 include, but are not limited to, silicon oxide, silicon nitride, silicon oxynitride, fluoride-doped silicate glass (FSG), a low-K dielectric material, and/or combinations thereof. In an example, the formation of the STI structure 102 includes filling trenches between the fins, for example, by a chemical vapor deposition (CVD) process, with a dielectric material. In some embodiments, the filled trench has a multi-layer structure, such as a thermal oxide liner layer filled with silicon nitride or silicon oxide.

The semiconductor device 100 further includes an inter-layer dielectric (ILD) layer over the STI. In the example configuration in FIG. 1B, the semiconductor device 100 includes an inter-layer dielectric (ILD) layer 104 over the STI structure 102. Example materials of the ILD layer 104 include, but are not limited to, SiNx, SiOx, SiON, SiC, SiBN, SiCBN, or combinations thereof. For simplicity, the ILD layer 104 is not illustrated in FIG. 1A. In some embodiments, the ILD layer 104 embeds therein the gate structures 121, 122, 123, and/or the corresponding gate spacers 131, 132, 133, 134, 135, 136. The ILD layer 104 further embeds therein the fins 115, 116, 118, 119 of the active regions 111, 112, in the corresponding metal contacts 141, 142, 143, and in the gap G between the gate structure and the adjacent metal contact.

The gate structures 121, 122, 123 extend along the Y-direction, across the active regions 111, 112. The gate structures 121, 122, and 123 may each include a plurality of gate electrodes isolated by the gate isolation sections 151, 152, and 153, respectively. For example, the gate structure 121 includes a gate electrode 181, and a portion of the gate electrode 181 is located in the transistor region 163 and is a constituent of the FinFET 168 as described above. Likewise, the gate structure 123 includes a first gate electrode 182a and a second gate electrode 182b isolated and separated by the gate isolation section 152, and the gate structure 123 includes a first gate electrode 183a and a second gate electrode 183b isolated and separated by the gate isolation section 153. The gate electrodes 182a, 182b, 183a, and 183b respectively correspond to the FinFETs 166, 169, 167, and 170. Example materials of the gate electrodes include a metal. The metal can be a work function metal such as Tungsten (W), Titanium nitride (TiN), Titanium oxide (TiO), Platinum (Pt), Nickel silicide (NiSi), Cobalt silicide (CoSi), Hafnium (Hf), Zirconium (Zr), Aluminum (Al), and Tantalum oxide (TaO). Other materials are within the scope of various embodiments. In some embodiments, each of the gate electrodes 181, 182a, 182b, 183a, and 183b further includes a gate dielectric layer 186 (shown in FIG. 1C) and a gate metal layer 187 (shown in FIG. 1C). The gate dielectric layer 186 is disposed on and in contact with the corresponding fin, and the gate metal layer 187 is disposed on the gate dielectric layer 186.

As mentioned above, five FinFETs 166, 167, 168, 169, and 170 are respectively formed in the corresponding transistor regions 161, 162, 163, 164, and 165. As an example, the FinFET 168 is formed by the gate electrode 181 and the active region 112. A gate of the FinFET 168 is formed by the gate electrode 181. The FinFET 168 is a two-fin FinFET and includes four drain-or-source regions (referred to herein as “source/drain” or “S/D”). A first S/D 171a of the FinFET 168 is defined by a region of the active region 112 on the fin 118 and on one side (e.g., the left side in FIG. 1A) of the gate electrode 181. A second S/D 171b of the FinFET 168 is defined by another region of the active region 112 on the fin 118 and on the opposite side (e.g., the right side in FIG. 1A) of the gate electrode 181. Likewise, a third S/D 171c of the FinFET 168 is defined by another region of the active region 112 on the fin 119 and on one side of the gate electrode 181, and a fourth S/D 171d of the FinFET 168 is defined by another region of the active region 112 on the fin 119 and on the opposite side of the gate electrode 181.

The gate spacers 131, 132, 133, 134, 135, and 136 are arranged along sides (or boundaries) of the corresponding gate structures. For example, the gate spacers 131 and 132 are arranged along longitudinal sides of the gate structure 121 in the Y-direction, the gate spacers 133 and 134 are arranged along longitudinal sides of the gate structure 122 in the Y-direction, the gate spacers 135, 136 are arranged along longitudinal sides of the gate structure 123 in the Y-direction. As one example, the gate structure 123 has two opposite sides, a left side 138 and a right side 139. The gate spacer 135 is disposed on the left side 138, and the gate spacer 136 is disposed on the right side 139. The gate spacers 131, 132, 133, 134, 135, and 136, include one or more dielectric materials for electrically isolating the corresponding gate electrodes from unintended electrical contact. Example dielectric materials of the gate spacers include, but are not limited to, silicon nitride, silicon oxynitride, and silicon carbide. In at least one embodiment, one or more of the gate spacers 131, 132, 133, 134, 135, 136 have a tapered profile.

Metal contacts 141, 142, and 143 extend in the same direction as the gate structures 121, 122, and 123 (i.e., along the Y-direction of FIG. 1A). Metal contacts used herein are sometimes also referred to as “metal on operation domain” or “MD.” Metal contacts 141 and 142 are within the second active region 112, and the metal contact 143 extends across the boundary (i.e., the line 110) between the first active region 111 and the second active region 112. The metal contacts 141, 142, and 143 are configured to electrically couple the underlying S/D regions of the corresponding FinFET with each other or with other circuitry of the semiconductor device. For example, the metal contacts 141 and 142 are configured to electrically couple the underlying S/D regions of the corresponding FinFET with other circuitry of the semiconductor device, whereas the metal contact 143 is an interconnector configured to electrically couple the underlying S/D regions of the FinFETs 166/167 (i.e., the S/D regions formed on the fins 115 and 116) and the underlying S/D regions of the FinFETs 169/170 (i.e., the S/D regions formed on the fins 118 and 119), respectively, across the boundary between the first active region 111 and the second active region 112.

In the illustrated example of FIGS. 1A-1B, boundaries of one or more metal contacts 141, 142, and 143 are spaced from boundaries of the adjacent gate structures 121, 122, and 123, in the X-direction. For example, metal contact 143 extends between the gate structures 122 and 123 and is aligned with and adjacent to the gate structures 122 and 123. A gap G is formed between a right side 137 (i.e., the right boundary) of metal contact 143 and from the left side 138 (i.e., the left boundary) of gate structure 123, and the gate spacer 135 is disposed on the left side 138 of the gate structure 123 in the gap G. A width of the gate spacer 135 may be less than or equal to a width of the gap G in the X-direction. In one or more embodiments described herein with reference to FIG. 1B, one or more of the metal contacts are self-aligned contacts (SAC) having boundaries defined at least partially by boundaries of the gate spacers 131, 132, 133, 134, 135, 136.

The layout of the semiconductor device 100 may include cutting patterns 155 and 156. The cutting pattern used herein is sometimes also referred to as “cut poly pattern,” “cut poly feature.” “cut poly region,” or “CPO.” Each of the CPOs 155 and 156 may include one or more gate isolation sections configured to separate the gate structures into multiple functional sections (e.g., gate electrodes) and logically isolate gate electrodes that correspond to different FinFETs. For example, the CPO 155 corresponds to gate structure 121 and includes gate isolation section 151. The gate isolation section 151 constitutes a portion or segment of the gate structure 121. The gate electrode 181 (i.e., the portion of the gate structure 121 located in the second active region 112 and corresponding to the FinFET 168) is isolated and separated from another portion of the gate structure 121 located in the first active region 111, by the gate isolation section 151. Likewise, the CPO 156 includes two gate isolation sections 152 and 153, respectively corresponding to the gate structures 122 and 123. The gate isolation section 152 constitutes a portion or segment of the gate structure 122 and is used to separate and isolate the gate electrodes 182a (located in the first active region 111) and 182b (located in the second active region 112). Similarly, the gate isolation section 153 constitutes a portion or segment of the gate structure 122 and is used to separate and isolate the gate electrode 183a (located in the first active region 111) and 183b (located in the second active region 112). The gate isolation sections 151, 152, and 153 respectively represent cut sections or patterning areas on the corresponding gate structures 121, 122, and 123.

The constituent material of the gate isolation section is different from the gate electrode(s) on the same gate structure. For example, the gate isolation section 151 of the CPO 155 includes polysilicon. In other words, the gate isolation section 151 functions as a conventional dummy gate section that logically isolates the gate electrode 181 from other sections in the gate structure 121. In contrast, the gate isolation sections 152 and 153 of the CPO 156 include a dielectric material, such as SiN, which is substantially less conductive than polysilicon or metal. Due to the dielectric property, the parasitic capacitance between the gate isolation section 152 and the adjacent metal contact 143 (i.e., in the region 159), as well as the parasitic capacitance between the gate isolation section 153 and the adjacent metal contact 143 (i.e., in the region 160) can be significantly reduced, as compared with the gate isolation section composed of polysilicon or metal. In other words, the gate isolation sections 152 and 153 composed of a dielectric material not only functions as a dummy gate section to logically isolate gate electrodes but also prevents formation of parasitic capacitor (e.g., in the regions 159 and 160). Accordingly, the gate isolation sections 152 and 153 can reduce or minimize the parasitic capacitance between the gate isolation section and the adjacent metal contact and/or prevent gain-to-drain leakage. As such, the performance of the FinFETs 166, 167, 169, and 170 in proximity to the gate isolation sections 152 and 153 can be improved.

It should be noted that conventional gate isolation sections generated by CPO patterning are usually composed of polysilicon (e.g., the gate isolation section 151), and parasitic capacitance between the gate isolation section composed polysilicon the adjacent metal contact can be significant or much higher as compared with the gate isolation section composed of dielectric material. Thus, the dielectric gate isolation sections according to the present disclosure are advantageous over the conventional gate isolation section with respect to the prevention or mitigation of parasitic capacitance.

In some embodiments, the layout of the semiconductor device 100 is represented by a plurality of masks generated by one or more processors and/or stored in one or more non-transitory computer-readable media. Other formats for representing the layout of the semiconductor device 100 are within the scope of various embodiments. Examples of a non-transitory computer readable recording medium include, but are not limited to, external/removable and/or internal/built-in storage or memory unit, e.g., one or more of an optical disc, such as a DVD, a magnetic disk, such as a hard disk, a semiconductor memory, such as a ROM, a RAM, a memory card, and the like. For example, the layout of the semiconductor device 100 is presented by at least one first mask corresponding to the active regions 111, 112, at least one second mask corresponding to the gate structures 122, 123, at least one third mask corresponding to the gate spacers 131, 132, 133, 134, 135, 136, at least one fourth mask corresponding to the metal contacts 141, 142, 143, at least one fifth mask corresponding to the CPO 155, and at least one sixth mask corresponding to the CPO 156. In some embodiments, a single mask can represent both the CPO 155 and the CPO 156.

### Example Methods for Fabricating Semiconductor Devices

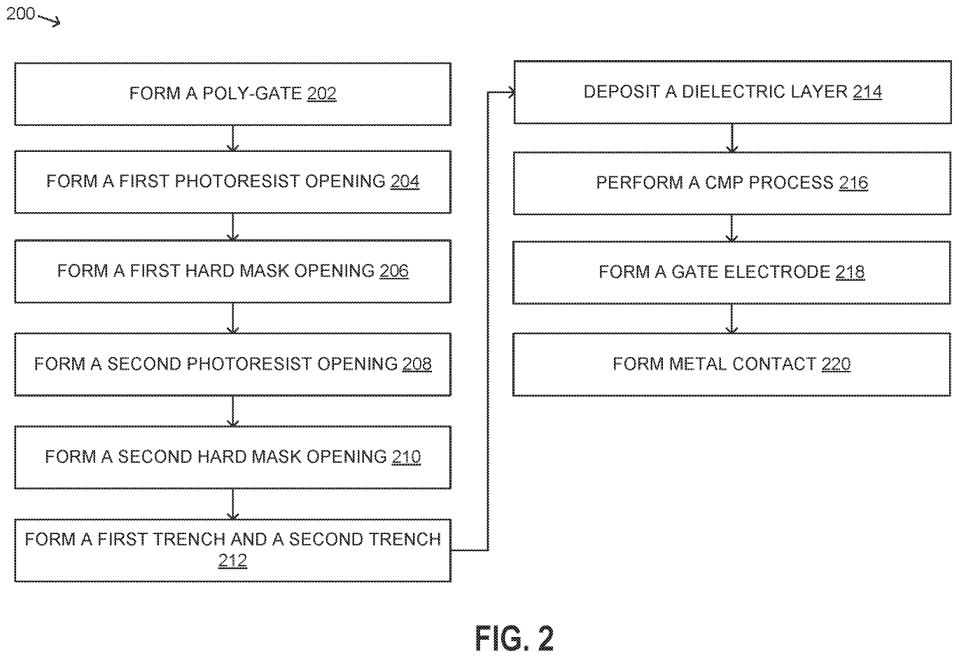

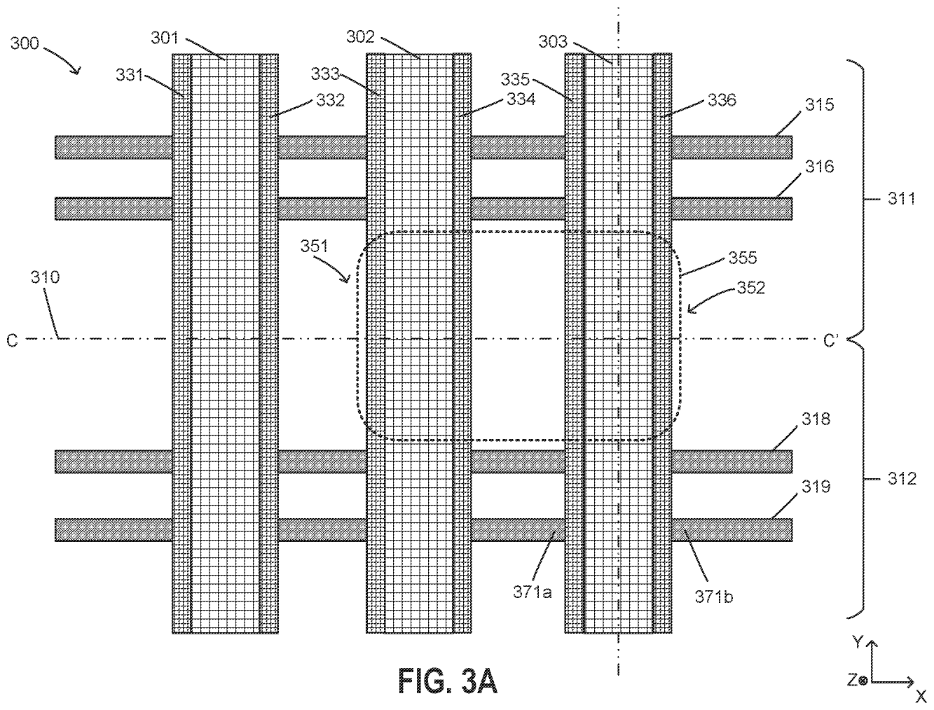

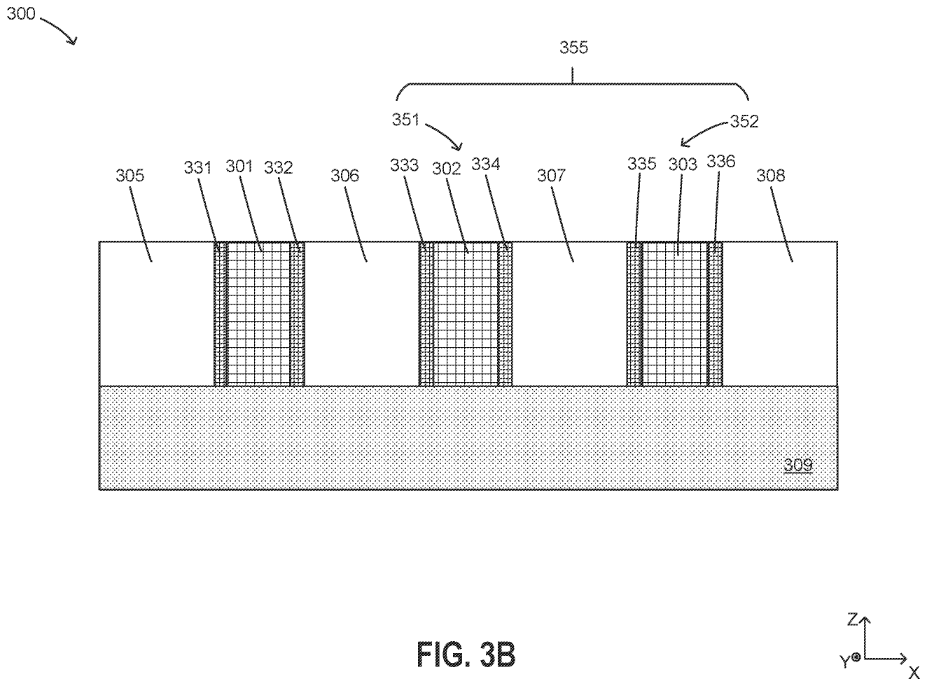

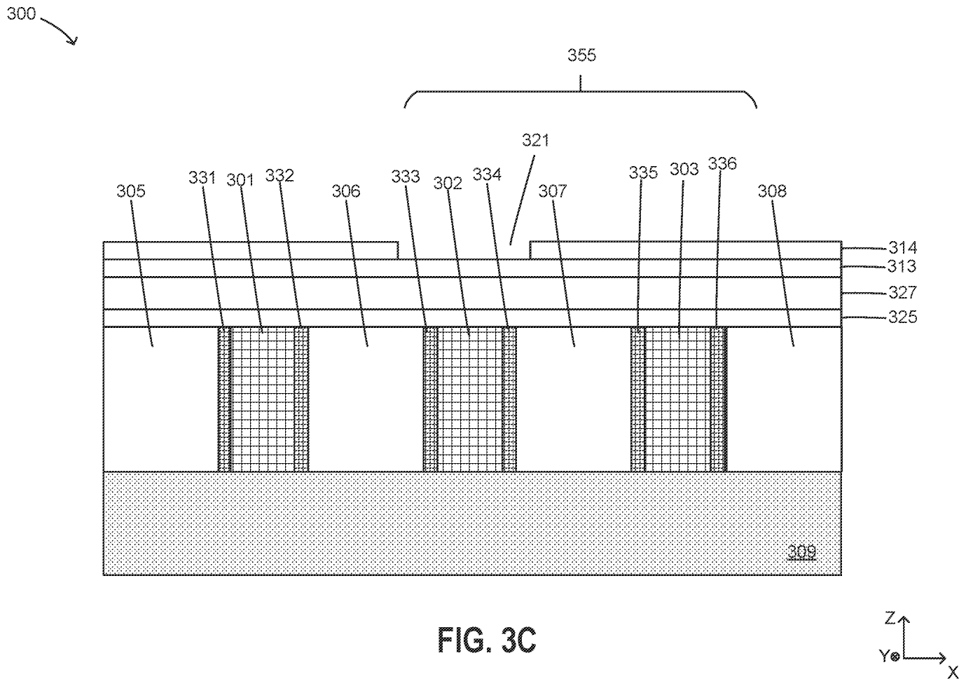

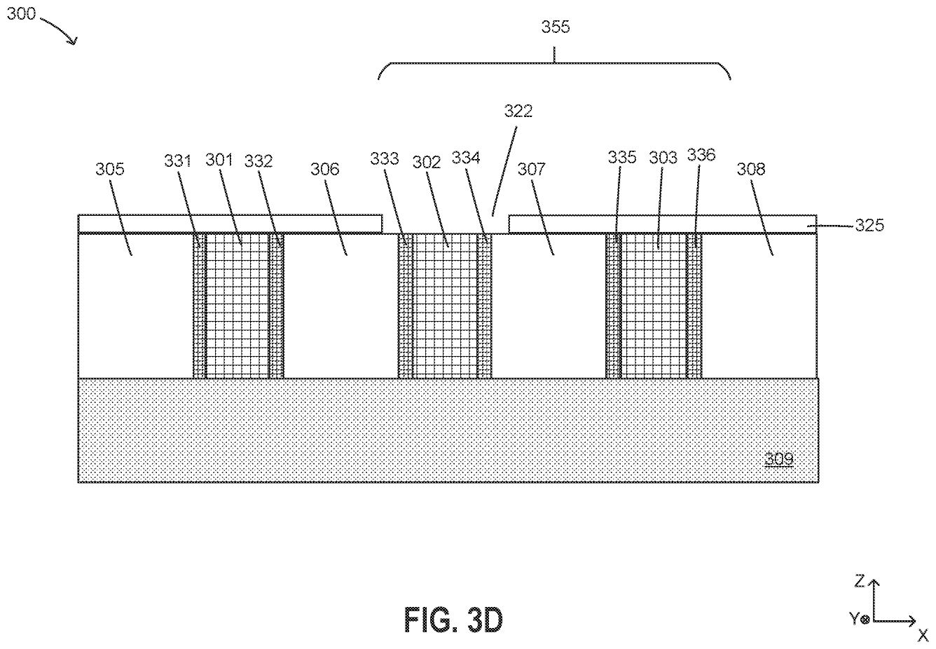

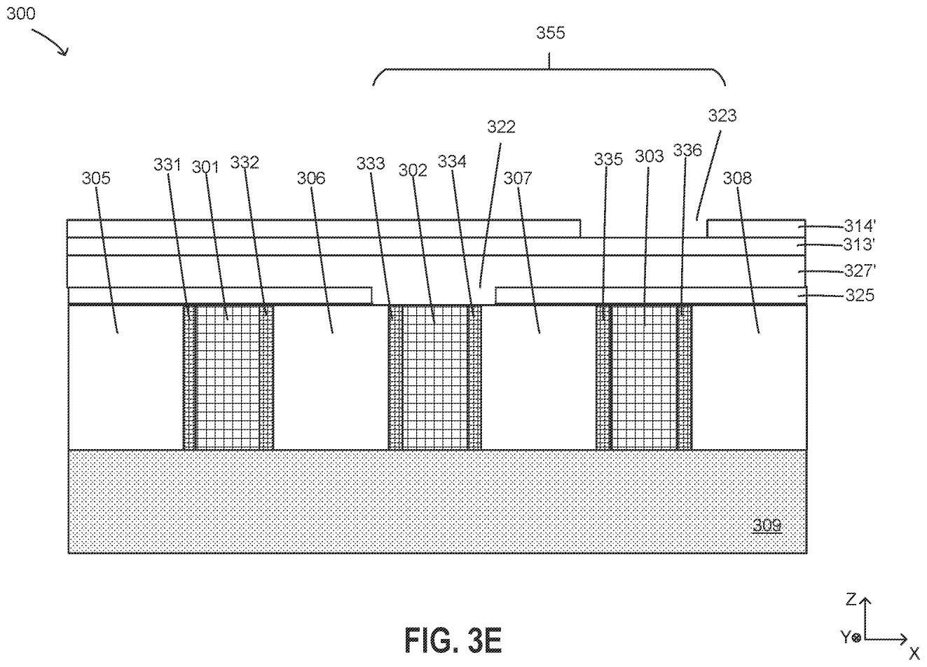

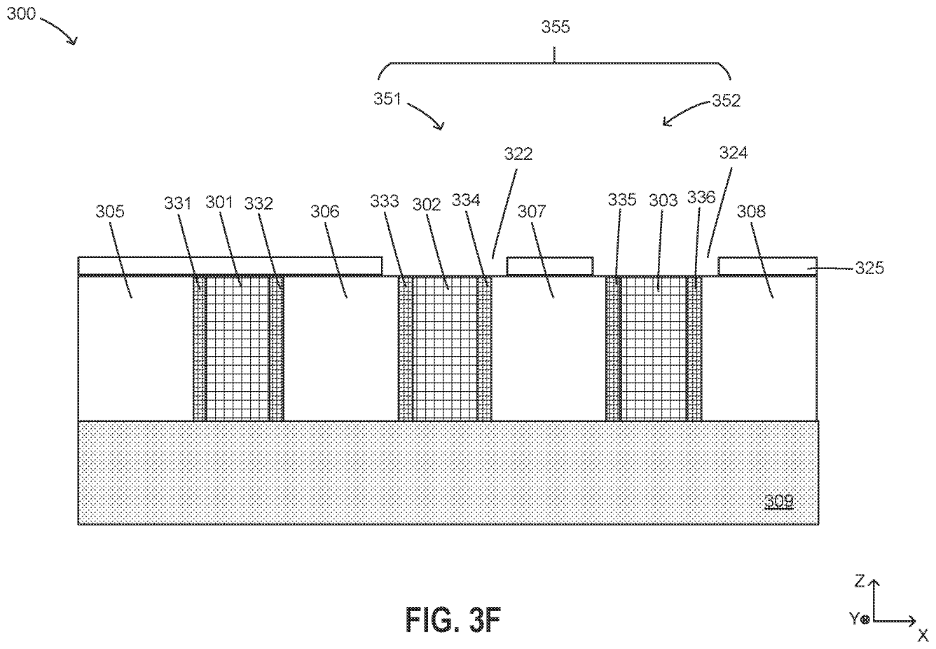

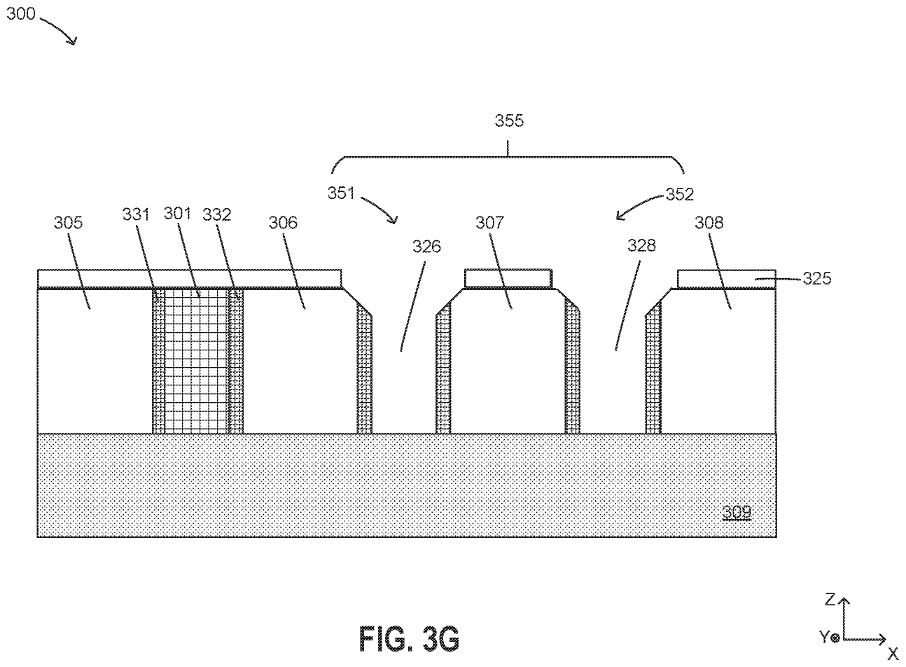

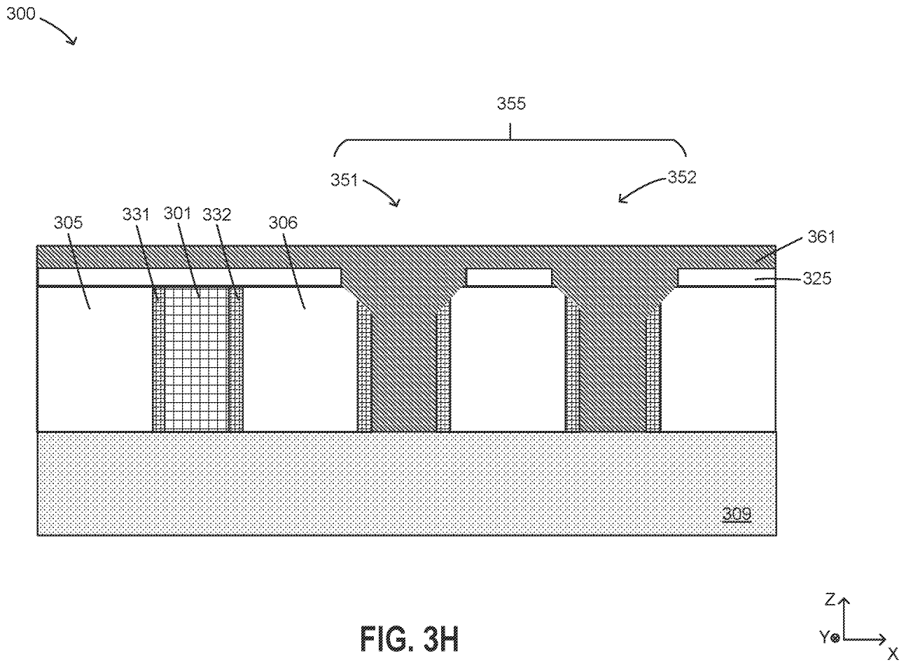

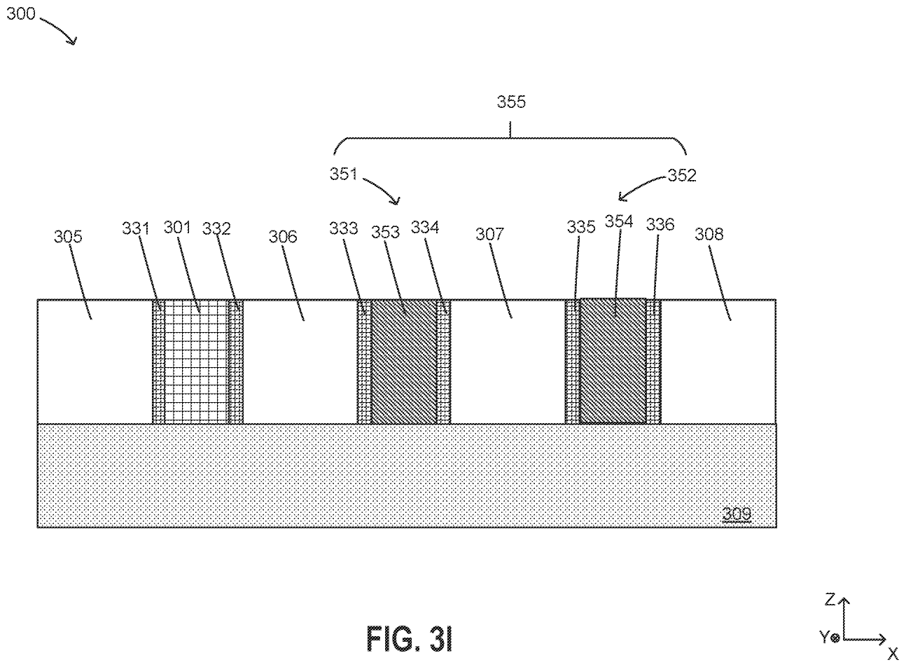

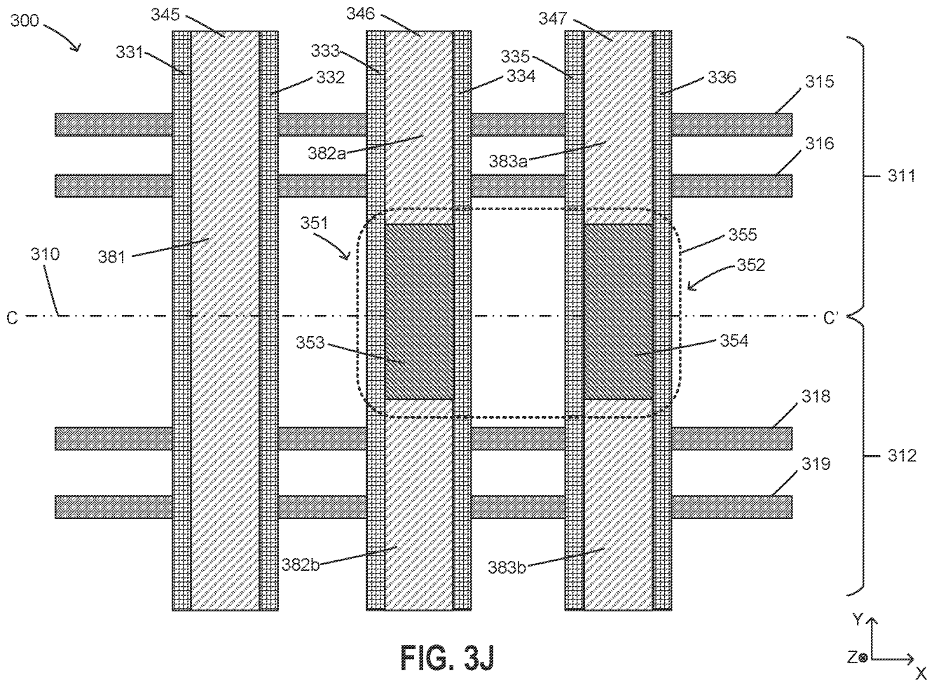

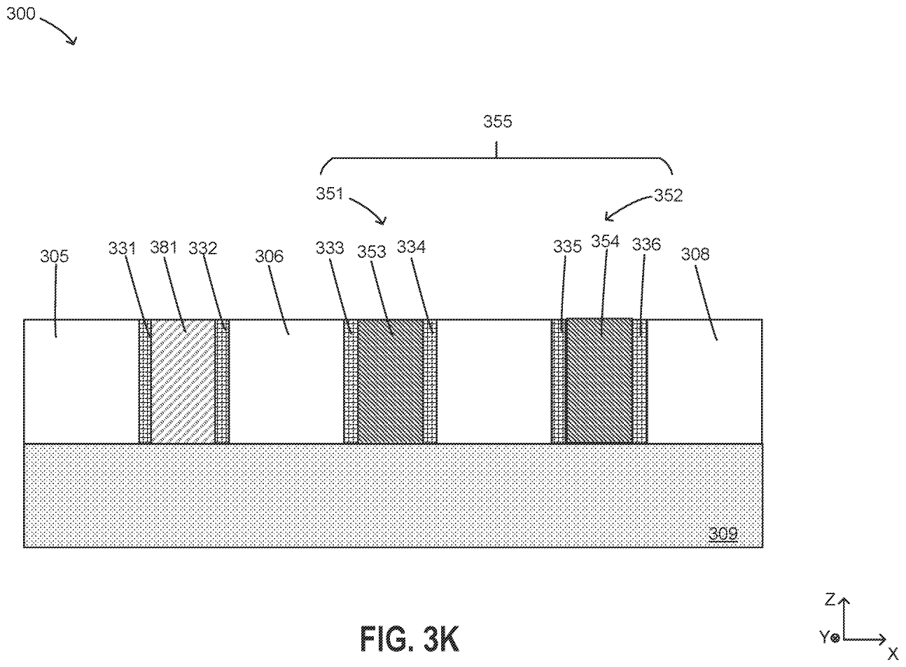

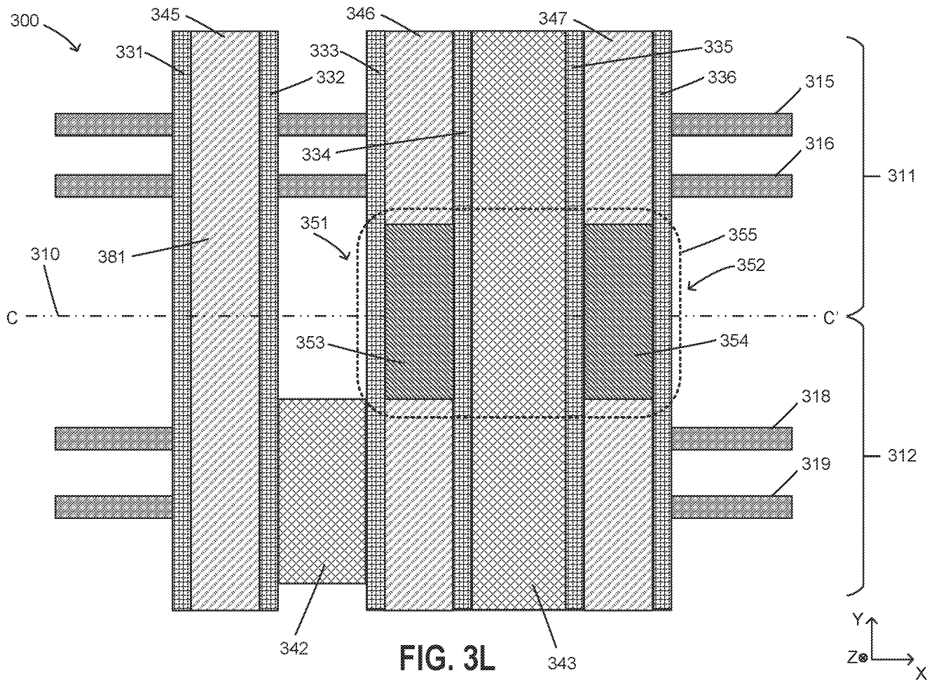

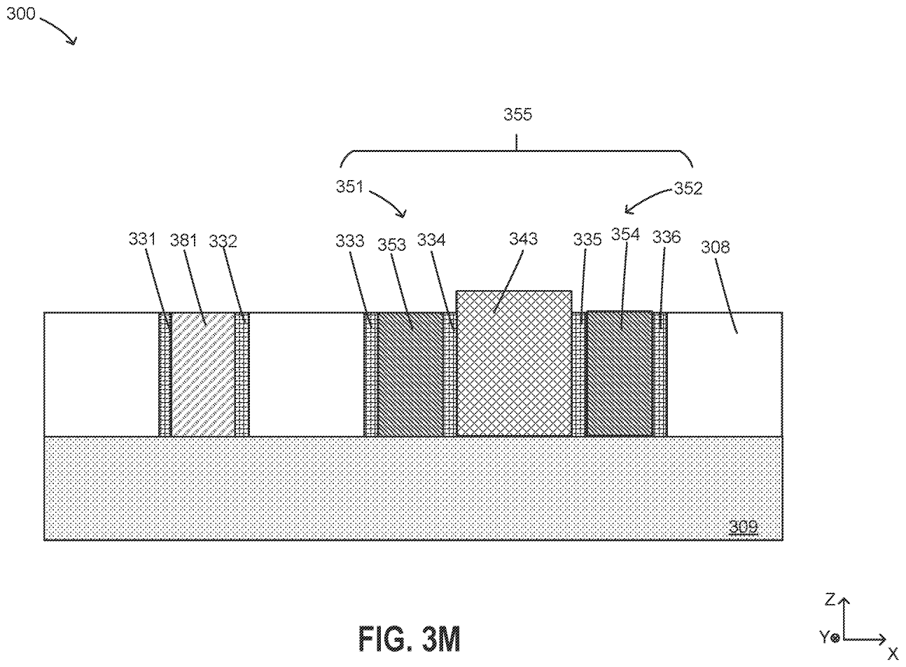

FIG. 2 is a flowchart diagram illustrating an example method 200 of fabricating a semiconductor device in accordance with some embodiments. FIGS. 3A-3M are schematic diagrams of a top view or a cross-sectional view illustrating the semiconductor device at various fabrication stages in accordance with some embodiments. For simplicity, some elements such as the substrate or gate spacers may not be illustrated in some of FIGS. 3A-3M.

In the illustrated example of FIG. 2, the method 200 includes operations 202, 204, 206, 208, 210, 212, 214, 216, 218, and 220. Additional operations may be performed. Also, it should be understood that the sequence of the various operations discussed above with reference to FIG. 2 is provided for illustrative purposes, and as such, other embodiments may utilize different sequences. These various sequences of operations are to be included within the scope of embodiments.

The method 200 starts at operation 202. At operation 202, a semiconductor device 300 is formed. FIG. 3A is a top view of the semiconductor structure 300. FIG. 3B is a cross-section view of the semiconductor device 300 along the line 310 in a direction from C to C′ shown in FIG. 3A. In the illustrated example, multiple fins 315, 316, 318, and 319 are formed along a latitudinal direction (i.e., the X-direction). Multiple poly-gates 301, 302, and 303 are formed along a longitudinal direction (i.e., the Y-direction). A first active region 311 and a second active region 312 may be separated by the line 310. The fins 315 and 316 are located in the first active region 311, and the fins 318 and 319 are located in the second active region 312. Each one of the poly-gates 301, 302, and 303 extends across the line 310, interconnecting the fins 315, 316, 318, and 319. Multiple gate spacers 331, 332, 333, 334, 335, and 336 are formed. Gate spacers 331 and 332 are disposed on the two sides of the poly-gate 301; gate spacers 333 and 334 are disposed on the two sides of the poly-gate 302; gate spacers 335 and 336 are disposed on the two sides of the poly-gate 303. A STI layer 309 is formed to define and electrically isolate the fins 315, 316, 318, and 319.

The fins may be formed by one or more suitable processes including, but not limited to, deposition, photolithography, and/or etching processes. In an example, the fins are formed by patterning and etching a portion of a silicon substrate. In another example, the fins are formed by patterning and etching a silicon layer deposited overlying an insulator layer (for example, an upper silicon layer of a silicon-insulator-silicon stack of an SOI substrate).

The poly-gates 301, 302, and 303 may be formed by suitable techniques. In one example, a PO mandrel process is performed. A polyimide mandrel is first formed on a semiconductor substrate, followed by deposition of a PO layer on the polyimide mandrel. The PO layer is then patterned and etched to form the poly-gates. The polyimide mandrel is then removed to complete the process. The formed poly-gates 301, 302, and 303 are composed of polysilicon or doped polysilicon.

In some embodiments, the poly-gates 301, 302, and 303 are formed using photolithography techniques. For example, a polysilicon layer is deposited, and a layer of photoresist is formed over a polysilicon layer by a suitable process, such as spin-on coating. The layer of photoresist is patterned to form patterned photoresist features by a proper lithography patterning process. The patterned photoresist features are then transferred by a dry etching process to the underlying polysilicon layer to form the poly gates. The patterned photoresist layer is stripped thereafter. The poly-gates 301, 302, and 303 may be used to form the gate structures in subsequent operations described below.

The gate spacers 331, 332, 333, 334, 335, and 336 may be formed over sidewalls of the corresponding poly-gates. In one example, a dielectric layer is formed over the poly-gates and covers sidewalls of the poly gates. Example dielectric materials include, but are not limited to, silicon oxide, silicon nitride, and silicon oxynitride. The dielectric layer is formed by CVD. PVD, atomic layer deposition (ALD), or other suitable techniques. An anisotropic etching is performed on the dielectric layer to form pairs of gate spacers on opposite sidewalls of the corresponding poly-gates.

S/D regions may be formed over the fins and between the facing gate spacers of the adjacent poly-gates. In one or more embodiments, portions of the fins, e.g., the fin 319, between the facing gate spacers of the adjacent poly gates are recessed to form S/D cavities having bottom surfaces lower than the top surface of the fin 319. For example, a biased etching process is performed to form the S/D cavities, using the hard masks on top of the poly gates and the gate spacers as etching masks. After the formation of the S/D cavities, S/D regions are produced by epi-growing a strained material in the S/D cavities. In some embodiments, a pre-cleaning process is performed to clean the S/D cavities with HF or other suitable solutions. Then, the strained material, such as silicon germanium (SiGe) is selectively grown by an LPCVD process to fill the S/D cavities. As illustrated in FIG. 3A, two S/D regions 371a and 371b are respectively formed in the fin 319 on the two opposite sides of the poly-gate 303.

In some embodiments, an ILD layer is deposited over the poly-gates, gate spacers, fins, and S/D regions thereon. Example materials of the ILDO layer include, but are not limited to, silicon oxide, spin-on glass (SOG), fluorinated silica glass (FSG), carbon-doped silicon oxide, other suitable dielectric materials, and/or combinations thereof. In some embodiments, the ILD layer is formed by a high-density plasma (HDP) process. In one or more embodiments, the ILD layer is planarized by a chemical mechanical polishing (CMP) process to remove a thickness of the ILD layer and the hard masks on tops of the poly-gates, and to expose top surfaces of the poly-gates. In the example shown in FIG. 3A, multiple ILD structures 305, 306, 307, and 308 are formed by the ILD layer, on the two opposite sides of each one of the poly-gates 301, 302, and 303.

At operation 204, a CPO region is selected or determined. The CPO region represents at least two CPO features including a first CPO feature and a second CPO feature. In some embodiments, a first photoresist pattern representing the first CPO feature is formed. As an example, a CPO region 355 (shown in FIG. 1A) is selected and determined according to an established design rule. The CPO region 355 is determined to form a first CPO feature 351 and a second CPO feature 352. The first CPO feature 351 corresponds to the poly-gate 302 and is designed to form a first dielectric gate isolation section (i.e., the first dielectric gate isolation section 353 of FIG. 3J) in the poly-gate 302. The second CPO feature 352 corresponds to the poly-gate 303 and is designed to form a second dielectric gate isolation section (i.e., the second dielectric gate isolation section 354 of FIG. 3J) in the poly-gate 303. The first and second CPO features 351 and 352 can be formed by using various techniques such as photolithography.

FIG. 3C is a cross-sectional view of the semiconductor device 300 at the stage of operation 204. In the illustrated example of FIG. 3C, multiple layers are formed on the semiconductor device 300. A hard mask layer 325 is deposited on the top surface of the poly-gates 301, 302, 303, the top surface of the gate spacers 331, 332, 333, 334, 335, and 336, as well as the top surface of the ILD structures 305, 306, 307, and 308. In some embodiments, the hard mask layer 325 includes SiN, although other materials such as silicon oxide can also be included in the hard mask layer 325 in alternative embodiments. A first bottom layer 327 is deposited on the hard mask layer 325. A first middle layer 313 is deposited on the first bottom layer 327. A first photoresist layer 314 is deposited on the first middle layer 313. A first patterned mask representing the first CPO feature 351 is used to selectively expose the first photoresist layer 314 to light to form a first photoresist opening 321 in the first photoresist layer 314. The first photoresist opening 321 is aligned with a selected section of the poly-gate 302 and represents the first CPO feature 351. The hard mask layer 325, the first bottom layer 327, and the first middle layer 313 may be formed in one or more embodiments by a method such as CVD or PVD.

At operation 206, the first photoresist pattern is transferred to the hard mask layer, and a first hard mask opening corresponding to the first photoresist opening is formed. The first hard mask opening represents the first CPO feature of the determined CPO region. FIG. 3D is a cross-sectional view of the semiconductor device 300 at the stage of operation 206. In the illustrated example of FIGS. 3C-3D, a patterning and etching process is performed to etch off the respective portions of the first middle layer 313, the first bottom layer 327, and the hard mask layer 325 aligned with the first photoresist opening 321 of the first photoresist layer 314. As a result, a first hard mask opening 322 in the hard mask layer 325 is formed. After forming the first hard mask opening 322, the remaining portions of the first middle layer 313, the first bottom layer 327, and the first photoresist layer 314 are removed. The first hard mask opening 322 of the hard mask layer 325 corresponds to the first photoresist opening 321 and represents the first CPO feature 351. The first hard mask opening 322 may be formed by common etching techniques such as a dry etching process, a wet etching process, a reactive ion etching (RIE) process, or a plasma-assisted etching process.

At operation 208, a second photoresist pattern representing the second CPO feature is formed, in a similar manner as the first photoresist pattern. FIG. 3E is a cross-sectional view of the semiconductor device 300 at the stage of operation 208. In the illustrated example of FIGS. 3D-3E, a second bottom layer 327′ is deposited on the hard mask layer 325, a second middle layer 313′ is deposited on the second bottom layer 327′, and a second photoresist layer 314′ is deposited on the second middle layer 313′. A second patterned mask representing the second CPO feature 352 is used to selectively expose the second photoresist layer 314′ to light to form a second photoresist opening 323 in the second photoresist layer 314′. The second photoresist opening 323 is aligned with a selected portion of the poly-gate 303 and represents the second CPO feature 352.

At operation 210, the second photoresist pattern is transferred to the hard mask layer, and a second hard mask opening corresponding to the second photoresist opening is formed. The second hard mask opening represents the second CPO feature of the determined CPO region. FIG. 3F is a cross-sectional view of the semiconductor device 300 at the stage of operation 210. In the illustrated example of FIGS. 3E-3F, a patterning and etching process is performed to etch off the respective portions of the second middle layer 313′, the second bottom layer 327′, and the hard mask layer 325 aligned with the second photoresist opening 323 of the second photoresist layer 314′ to form a second hard mask opening 324 in the hard mask layer 325. After forming the second hard mask opening 324, the remaining portions of the second middle layer 313′, the second bottom layer 327′, and the second photoresist layer 314′ are removed. The second hard mask opening 324 of the hard mask layer 325 corresponds to the second photoresist opening 323 and represents the second CPO feature 352.

It should be noted that the first and second hard mask openings 322 and 324 may be formed in a simplified process using a single patterned photomask representing both the first and second CPO features, using high-definition photolithography techniques such as Extreme Ultraviolet (EUV) lithography. In other embodiments, multiple CPO regions may be selected and more than two hard mask openings representing more than two CPO features may be formed simultaneously using a single patterned photomask.

At operation 212, a selected portion of the poly-gate corresponding to the CPO region 355 is removed to form a trench. FIG. 3G is a cross-sectional view of the semiconductor device 300 at the stage of operation 212. In the illustrated example of FIGS. 3F-3G, a selected portion of the poly-gate 302 corresponding to the first CPO feature 351 and a selected portion of the poly-gate 303 corresponding to the CPO feature 352 are removed by a patterning and etching process, respectively through the hard mask openings 322 and 324. As a result, two trenches 326 and 328 are formed respectively in the poly-gate 302 and poly-gate 303.

At operation 214, a dielectric layer is deposited. FIG. 3H is a cross-sectional view of the semiconductor device 300 at the stage of operation 214. In the illustrated example of FIGS. 3G-3H, a dielectric layer 361 is deposited on the hard mask layer 325 and fills the trenches 326 and 328 with a dielectric material. In some embodiments, the dielectric layer is a SiN layer deposited by ALD, and the dielectric material filled in the trenches 326 and 328 is SiN.

At operation 216, a CMP process is performed. FIG. 3I is a cross-sectional view of the semiconductor device 300 at the stage of operation 216. In the illustrated example of FIGS. 3H-3I, a CMP process is performed to expose a top surface of the poly-gate 301 to achieve a relatively flat top surface of the poly-gate, IDL structures, gate spacers, and dielectric gate isolation sections. As a result, two dielectric gate isolation sections 353 and 354 are respectively formed in the poly-gates 302 and 303.

At operation 218, gate electrodes are formed. FIG. 3J is a top view of the semiconductor device 300 at the stage of operation 218. FIG. 3K is a cross-sectional view of the semiconductor device 300 at the stage of operation 218. In the illustrated example of FIGS. 3A-3B and 3I-3K, gate electrode 181 is formed by replacement of the poly-gate 301 with a metal. Similarly, gate electrodes 182a and 182b are formed by replacement of the portions of poly-gate 302 separated by the dielectric gate isolation section 353 with a metal. Gate electrodes 183a and 183b are formed by replacement of the portions of poly-gate 303 separated by the dielectric gate isolation section 354 with a metal. As mentioned above, the metal may be a work function metal. In some embodiments, a patterning and etching process is performed to remove the portions of poly-gates where gate electrodes are to be formed, a gate dielectric layer (e.g., the gate dielectric layer 186 of FIG. 1C) is deposited, a gate metal layer is deposited on the gate dielectric layer, and a CMP process is performed to remove excess gate metal layer and to form flat and uniform gate electrodes. The gate electrode 381 constitutes the gate structure 345. The gate electrodes 382a and 382b and the dielectric gate isolation section 353 constitute the gate structure 346. The gate electrodes 383a and 383b and the dielectric gate isolation section 354 constitute the gate structure 347.

At operation 220, metal contacts are formed. Metal contacts can be formed by replacement of the portions of the ILD structures where the metal contacts are to be formed with a metal. FIG. 3L is a top view of the semiconductor device 300 at the stage of operation 220. FIG. 3M is a cross-sectional view of the semiconductor device 300 at the stage of operation 220. In the illustrated example of FIGS. 3I-3M, the metal contact 342 is formed between the gate spacers 332 and 333 in the second active region 312. The metal contact 343 is formed between the gate spacers 335 and 336 and extends across the line 310 to both the first active region 311 and the second active region 312. The metal contact 342 couples the fins 318 and 319, and the metal contact 342 couples fins 315, 316, 318, and 319, and interconnects the fins 316 and 318 from different active regions. In some embodiments, the metal contacts are formed by performing a metal on operation domain (MD) process using a deposition technique such as PVD or CVD. The semiconductor device 300 resulting from operation 220 includes dielectric gate isolation sections 353 and 354 in the CPO region 355. As described above, the parasitic capacitance between the dielectric gate isolation section 353 and the adjacent metal contact 343 as well as the gain-to-train leakage can be significantly reduced or minimized. Similarly, the parasitic capacitance between the dielectric gate isolation section 354 and the adjacent metal contact 343 can also be significantly reduced or minimized. Accordingly, the overall performance of the semiconductor device 300 can be improved.

### Additional Examples of Semiconductor Devices

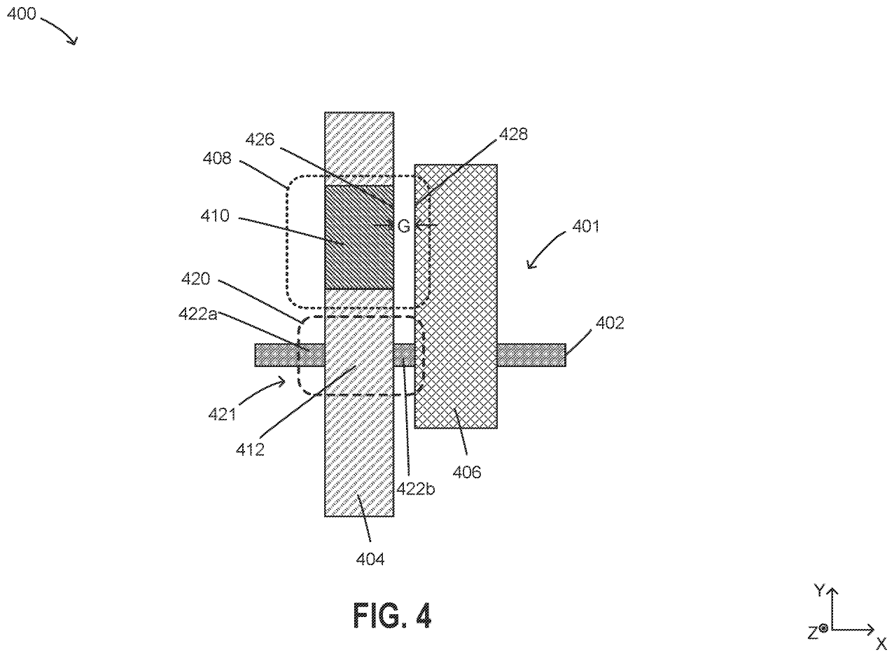

FIG. 4 is a schematic diagram illustrating a top view of a layout of a semiconductor device 400 in accordance with some embodiments. The semiconductor device 400 is similar to the semiconductor device 100 shown in FIG. 1A. In the illustrated example, the semiconductor device 400 includes a substrate 401, a fin 402 formed on the substrate 401 and extending in a first direction (i.e., the latitudinal direction or the X-direction), a gate structure 404 formed on the fin 402 and extending in a second direction (i.e., the longitudinal direction or the Y-direction), a metal contact 406 formed on the fin 402 extending in the second direction and disposed on the fin 402. The metal contact 406 is adjacent to the gate structure 404 and may be spaced from the gate structure 404 by a gap. A gate spacer (e.g., the gate spacer 132 shown in FIG. 1A) may be disposed in the gap between the gate structure 404 and the metal contact 406. The gate spacer may be composed of a dielectric material.

The gate structure 404 may include a dielectric gate isolation section 410 in a CPO region 408 and a gate electrode 412 in a transistor region 420. The CPO region may be determined by a pre-established rule to reduce or minimize the parasitic capacitance between the gate structure and the adjacent metal contact. The dielectric gate isolation section 410 may be formed in the CPO region 408 by any method according to the present disclosure. A FinFET 421 may be formed in the transistor region 420. The FinFET 421 may include the gate electrode 412, two S/D regions 422a and 422b separated by the gate electrode 412 and formed in the fin 402 within the transistor region 420. The gate electrode 412 may further include a gate dielectric layer (e.g., the gate dielectric layer 186 of FIG. 1C) in contact with the fin 402 and a gate metal layer disposed on the gate dielectric layer.

The dimension of the CPO region 408 can vary depending on design requirements. For example, the CPO region 408 may have a width (i.e., the latitudinal dimension in the X-direction) of about 10 nm to about 100 nm, or from about 20 nm to about 50 nm. The CPO region 408 may have a length (i.e., the dimension in the Y-direction) from about 10 nm to about 200 nm, or from about 16 nm to about 100 nm.

The dielectric gate isolation section 410 may have a width (i.e., the latitudinal dimension in the X-direction) that is the same as the width of the gate structure 404 (i.e., extending fully from one side of the gate structure 404 to the other side in the X-direction). The dielectric gate isolation section 410 may have a length (i.e., the longitudinal dimension in the Y-direction) variable depending on design requirements such as the length of the adjacent metal contact. At least a portion of the dielectric gate isolation section 410 and at least a portion of the metal contact 406 are aligned and in proximity in the latitudinal direction (i.e., the X-direction) to form a gap (G) between a boundary 426 of the dielectric gate isolation section 410 and a boundary 428 of the adjacent metal contact 406. In some embodiments, at least a portion of the gate isolation section 410 and at least a portion of the adjacent metal contact 406 are overlapped in the latitudinal direction. In some embodiments, all or substantially all the gate isolation section 410 in the second longitudinal direction (i.e., the Y-direction) is overlapped with a portion of the metal contact 406 in the latitudinal direction. In some embodiments, a substantial portion of the metal contact 406 and a substantial portion of the gate isolation section 410 on the same side of the fin 402 are overlapped in the latitudinal direction. It should be noted that the longitudinal dimension (i.e., dimension in the Y-direction) of the gate isolation section 410 may be adjusted to maximize the overlap with the metal contact 406 along the longitudinal direction. As mentioned above, because of the dielectric nature of the dielectric gate isolation section 410, the parasitic capacitance between the dielectric gate isolation section 410 and the adjacent metal contact 406 can be minimized, and the performance of the nearby FinFET 421 can be improved.

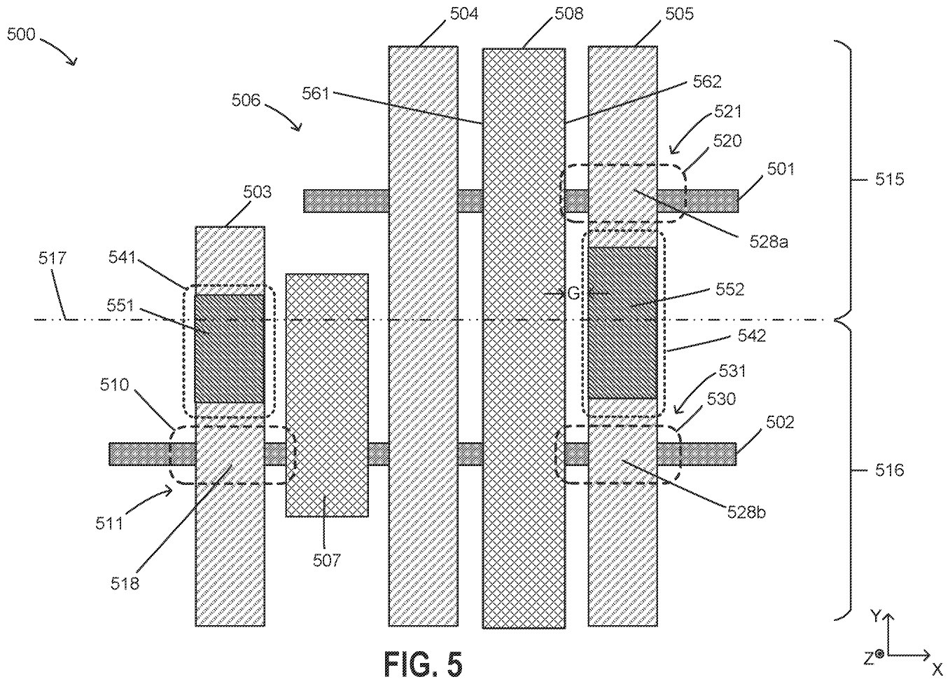

FIG. 5 is a schematic diagram illustrating a top view of a layout of a semiconductor device 500 in accordance with some embodiments. The semiconductor device 500 is similar to the semiconductor device 100 shown in FIG. 1A. In the illustrated example, the semiconductor device 500 includes a substrate 506. The semiconductor device 500 includes a first active region 515 and a second active region 515 divided by an imaginary line 517. The semiconductor device 500 includes a first fin 501 disposed in the first active region 515, and a second fin 502 disposed in the second active region 516. The fins 501 and 502 extend in a latitudinal direction. The semiconductor device 500 includes a first gate structure 503, a second gate structure 504, and a third gate structure 505, all extending in the longitudinal direction across the boundary between the first and the second active regions 515 and 516. The first gate structure 503 is coupled to the second fin 502. Both the second and third gate structures 504 and 505 are coupled to and interconnect the first and the second fins 501 and 502. The semiconductor device 500 includes a first metal contact 507 and a second metal contact 508, both extending in the longitudinal direction (i.e., the same direction as the gate structures 503, 504, 505). The first metal contact 507 is coupled to the second fin 502 and disposed between the gate structures 503 and 504, and thus is adjacent to both the gate structures 503 and 504. The second metal contact 508 is coupled to and interconnects the first and second fins 501 and 502. The second metal contact 508 is disposed between the second and third gate structures 504 and 505. The second metal contact 508 has a first side 561 and a second side 562 opposite to the first side 561. The first side 561 is adjacent to the second gate structure 504, and the second side 562 is adjacent to the third gate structure 505.

The semiconductor device 500 includes at least two CPO regions (i.e., the first CPO region 541 and the second CPO region 542). The first gate structure 503 includes a first dielectric gate isolation section 551 within the first CPO region 541 and a gate electrode 518 separate from the first dielectric gate isolation section 551. Likewise, the third gate structure 505 includes a second dielectric gate isolation section 552 within the second CPO region 542 and two gate electrodes 528a and 528b separated by the second dielectric gate isolation section 552. The gate electrodes 518, 528a, and 528b are respectively located in a first transistor region 510, a second transistor region 520, and a third transistor region 530. At least three FinFETs, 511, 521, and 531 can be respectively formed in the first, second, and third transistor regions 510, 520, and 530.

A latitudinal distance between the first and second CPO regions 541 and 542 can vary depending on design rules and requirements. In some embodiments, the latitudinal distance is at least 30 nm, or at least 50 nm, or at least 54 nm. In some embodiments, the first and second CPO regions 541 and 542 can each span over multiple gate structures (e.g., from 1 gate structure to 10 gate structures) in the latitudinal direction.

Although not illustrated in FIG. 5, it can be understood that additional dielectric gate isolation sections can be formed, for example, in the gate structure 504, in a similar manner as described with reference to FIGS. 3A-3M. In some embodiments, the dielectric gate isolation sections of the semiconductor device 500 may be formed simultaneously or by a single patterning and etching process.

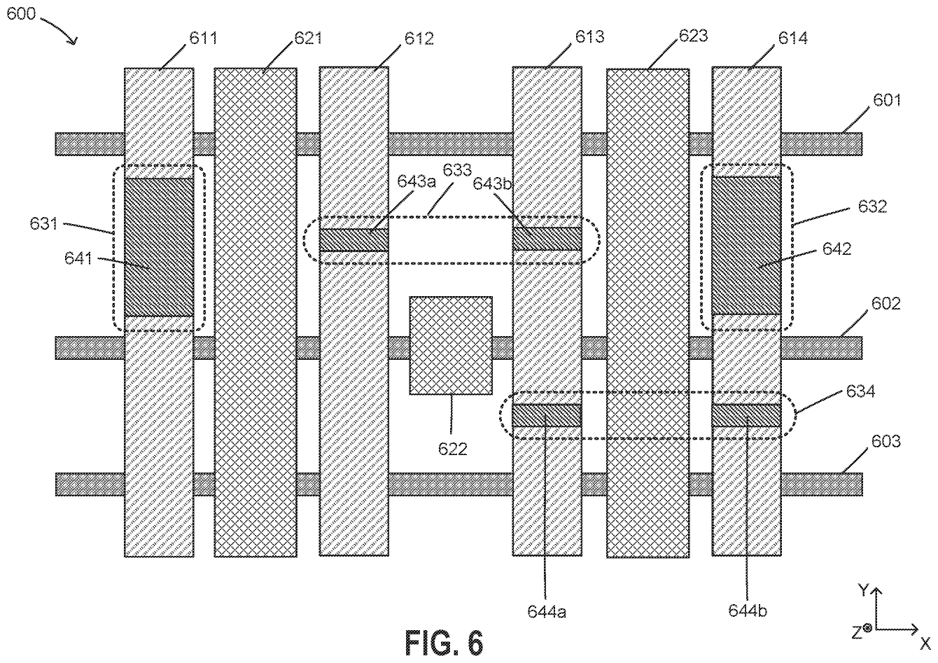

FIG. 6 is a schematic diagram illustrating a top view of a layout of a semiconductor device 600 in accordance with some embodiments. The semiconductor device 600 is similar to the semiconductor device 100 shown in FIG. 1A. In the illustrated example, the semiconductor device 500 includes three fins 601, 602, and 603, four gate structures 611, 612, 613, and 614, and three metal contacts 621, 622, and 623. Multiple FinFETs can be formed in multiple transistor regions of the semiconductor device 600. The semiconductor device 600 includes multiple CPO regions, including a first CPO region 631, a second CPO region 632, a third CPO region 633, and a fourth CPO region 634. Two dielectric gate isolation sections 641 and 642 are respectively formed in the first and second CPO regions 631 and 632. Two conventional dummy gate sections 643a and 643b are formed in the third CPO region 633, and two conventional dummy gate sections 644a and 644b are formed in the fourth CPO region 634.

It is noted that the first and second dielectric gate isolation sections 641 and 642 are composed of a dielectric material such as SiN. In contrast, the dummy gate sections 643a. 643b, 644a, and 644b are composed of polysilicon, which is a conductive material. The first dielectric gate isolation section 641 can be used to effectively reduce or minimize parasitic capacitance between the gate structure 611 and metal contact 621. Similarly, the second dielectric gate isolation section 642 can be used to effectively reduce or minimize parasitic capacitance between the gate structure 614 and metal contact 623. However, the conventional dummy gate sections 643a, 643b, 644a, and 644b can only be used to isolate gate electrodes in the corresponding gate structure but may not reduce the parasitic capacitance between the gate structure and adjacent metal contact.

In some embodiments, the two CPO regions 631 and 632 may be patterned using a single mask, and the two dielectric gate isolation sections 641 and 642 may be formed using a single mask or simultaneously in a single process. In some embodiments, the four CPO regions 631, 632, 633, and 634 may be patterned using a single mask.

### SUMMARY

In accordance with some aspects of the disclosure, a semiconductor device is provided. In one example, a semiconductor device include: a substrate, at least one fin formed on the substrate, at least one gate structure formed on the at least one fin, and at least one metal contact formed on the at least one fin. The at least one fin extends along a first horizontal direction, the at least one gate structure extends along a second horizontal direction, the at least one metal contact extends along a second horizontal direction and is adjacent to the gate structure, and the second horizontal direction is substantially perpendicular to the first horizontal direction. The at least one gate structure further includes: at least one gate electrode coupled to the one or more fins and at least one dielectric gate isolation section separated from the at least one gate electrode. The at least one dielectric gate isolation section includes a dielectric material. A portion of the dielectric gate isolation section is aligned with a portion of the metal contact adjacent and proximate to the dielectric gate isolation section in the first horizontal direction.

In another example, a semiconductor device include: a substrate, a first active region and a second active region formed over the substrate, a first fin and a second fin respectively formed in the first and second active regions. The first and second fins extend along a first horizontal direction. The semiconductor device further includes a first gate structure and a first metal contact. The first gate structure and the first metal contact are formed on the first and second fins and extend along a second horizontal direction across a boundary between the first and second active regions. The first gate structure is adjacent to a first side of the first metal contact. The second horizontal direction is substantially perpendicular to the first horizontal direction. The first gate structure further includes: a first gate electrode and a second gate electrode respectively coupled to the first and second fins, and a first gate isolation section between the first and second gate electrodes. The first gate isolation section isolates and interconnects the first and second gate electrodes. The first gate isolation section includes a dielectric material. A portion of the first gate isolation section is adjacent and proximate to the first side of the first metal contact and aligned with a portion of the first metal contact in the first horizontal direction.

In accordance with some aspects of the disclosure, a method for fabricating a semiconductor device is provided. In one example, the method includes forming at least one fin and at least one poly-gate on a substrate. The at least one fin extends along a first horizontal direction, the at least one poly-gate is formed on the at least on fin and extends along a second horizontal direction, and the second horizontal direction is substantially perpendicular to the first horizontal direction. The method further includes forming a hard mask layer on the at least one poly-gate, performing a patterning and etching process to remove a first selected portion of the at least one poly-gate and form a trench, depositing a dielectric layer to fill the trench with a dielectric material, performing a chemical mechanical polishing (CMP) process to form a dielectric gate isolation section in the trench, forming at least one gate electrode by replacing a second selected portion of the poly-gate with a work function metal, and forming a metal contact on the at least one fin. The metal contact extends along the second horizontal direction and is adjacent to a portion of the dielectric gate isolation section.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
at least one fin formed on the substrate, the at least one fin extending along a first horizontal direction;
at least one gate structure formed on the at least one fin and extending along a second horizontal direction, the second horizontal direction being substantially perpendicular to the first horizontal direction; and
at least one metal contact formed on the at least one fin extending along the second horizontal direction and adjacent to the gate structure;
wherein the at least one gate structure further comprises:
at least one gate electrode coupled to the at least fin; and
at least one dielectric gate isolation section separated from the at least one gate electrode, the at least one dielectric gate isolation section comprising a dielectric material;
wherein a portion of the dielectric gate isolation section is aligned with a portion of the metal contact adjacent and proximate to the dielectric gate isolation section in the first horizontal direction.

2. The semiconductor device of claim 1, further comprising:
a gate spacer disposed on one side of the gate structure, wherein at least a portion of the gate spacer is disposed between the dielectric gate isolation section and the adjacent metal contact.

3. The semiconductor device of claim 1, wherein two source/drain regions are formed respectively on two sides of the gate electrode, and wherein the gate electrode and the two source/drain regions form a fin field effect transistor (FinFET).

4. The semiconductor device of claim 1, wherein the gate electrode further comprises:
a gate dielectric layer in contact with the fin; and
a gate metal layer disposed on the gate dielectric layer.

5. The semiconductor device of claim 1, wherein the dielectric material of the dielectric gate isolation section is silicon nitride (SiN).

6. The semiconductor device of claim 1, wherein the dielectric gate isolation section has a length in the second horizontal direction from 16 nm to 100 nm.

7. The semiconductor device of claim 1, wherein the dielectric gate isolation section extends in a full width of the gate structure along the first horizontal direction.

8. The semiconductor device of claim 1, further comprising at least one via contact disposed on the gate electrode or the metal contact.

9. A semiconductor device comprising:
a substrate;
a first active region and a second active region formed over the substrate;
a first fin and a second fin respectively formed in the first and second active regions, the first and second fins extending along a first horizontal direction;
a first gate structure formed on the first and second fins and extending along a second horizontal direction across a boundary between the first and second active regions, the second horizontal direction being substantially perpendicular to the first horizontal direction; and
a first metal contact formed on the first and second fins and extending along the second horizontal direction across the boundary between the first and second active regions, wherein the first gate structure is adjacent to a first side of the first metal contact;
wherein the first gate structure further comprises:
a first gate electrode and a second gate electrode respectively coupled to the first and second fins; and
a first gate isolation section between the first and second gate electrodes, wherein the first gate isolation section isolates and interconnects the first and second gate electrodes, and the first gate isolation section comprises a first material, the first material being a dielectric material,
wherein a portion of the first gate isolation section is adjacent and proximate to the first side of the first metal contact and aligned with a portion of the first metal contact in the first horizontal direction.

10. The semiconductor device of claim 9, wherein the dielectric material is SiN.

11. The semiconductor device of claim 9, wherein the first gate isolation section extends across the boundary between the first and second active regions.

12. The semiconductor device of claim 9, further comprising:
a second gate structure formed on the first and second fin and extending in the second horizontal direction across the boundary between the first and second active regions, the second gate structure being adjacent to a second side of the first metal contact,
wherein the second gate structure further comprises:
a third gate electrode and a fourth gate electrode respectively coupled to the first and second fins; and
a second gate isolation section between the third and fourth gate electrodes, wherein the first gate isolation section isolates and interconnects the third and fourth gate electrodes and comprises a second material;
wherein a portion of the second gate isolation section is adjacent and proximate to the second side of the first metal contact and aligned with a portion of the first metal contact in the first horizontal direction.

13. The semiconductor device of claim 12, wherein the first and second gate isolation sections are substantially aligned in the first horizontal direction.

14. The semiconductor device of claim 12, wherein the first and second gate isolation sections are spaced with a distance of at least 54 nm in the first horizontal direction.

15. The semiconductor device of claim 12, wherein the first and second gate isolation sections are formed simultaneously.

16. The semiconductor device of claim 12, wherein the first and second materials are the same.

17. The semiconductor device of claim 9, further comprising:
a third gate structure formed on the second fin and extending in the second horizontal direction; and
a second metal contact formed on the second fin and extending in the second horizontal direction, the second metal contact being adjacent to the third gate structure,
wherein the third gate structure further comprises:
a fifth gate electrode coupled to the second fin; and
a third gate isolation section comprising a third material;
wherein a portion of the third gate isolation section is adjacent and proximate to a side of the second metal contact and aligned with a portion of the second metal contact in the first horizontal direction.

18. The semiconductor device of claim 17, wherein the third material is the same as the first material.

19. The semiconductor device of claim 17, wherein the third material is a conductive material.

20. A method of fabricating a semiconductor device, the method comprising:
forming at least one fin and at least one poly-gate on a substrate, wherein the at least one fin extends along a first horizontal direction, the at least one poly-gate is formed on the at least on fin and extends along a second horizontal direction, and the second horizontal direction is substantially perpendicular to the first horizontal direction;
forming a hard mask layer on the at least one poly-gate;
performing a patterning and etching process to remove a first selected portion of the at least one poly-gate and form a trench;
depositing a dielectric layer to fill the trench with a dielectric material;
performing a chemical mechanical polishing (CMP) process to form a dielectric gate isolation section in the trench;
forming at least one gate electrode by replacing a second selected portion of the poly-gate with a work function metal; and
forming a metal contact on the at least one fin, the metal contact extending along the second horizontal direction and adjacent to a portion of the dielectric gate isolation section.
